(19) United States
(12) Patent Application Publication
(10) Pub. No.: US 2022/0310716 A1
(43) Pub. Date: Sep. 29, 2022

(54) DISPLAY PANEL AND MANUFACTURING METHOD THEREOF

(71) Applicant: WUHAN CHINA STAR OPTOELECTRONICS SEMICONDUCTOR DISPLAY TECHNOLOGY CO., LTD., Wuhan (CN)

(72) Inventor: Congcong Fan, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 17/267,490

(22) PCT Filed: Sep. 9, 2020
(86) PCT No.: PCT/CN2020/114179

§ 371 Date: Feb. 9, 2021

(30) Foreign Application Priority Data
Jul. 13, 2020 (CN) 202010669406.4

(51) Int. Cl. H01L 27/32; H01L 51/56; H01L 51/50

(52) U.S. Cl. CPC H01L 27/3227; H01L 27/3246; H01L 51/56; H01L 51/5056; H01L 51/5072

(57) ABSTRACT

The present disclosure provides a display panel and a manufacturing method thereof. The display panel includes a display area, a plurality of light-emitting units uniformly distributed in the display area, and at least one organic photodetection unit arranged at an edge or a corner of the display area.

### FIELD OF INVENTION

The present disclosure relates to field of display technology, in particular to a display panel and manufacturing method thereof.

### BACKGROUND OF INVENTION

As we all know, ultraviolet rays have serious impact on human skin. According to reports, only 10% of aging of human skin is caused by physiological aging, while 90% of aging that really damages the skin is caused by the ultraviolet rays from sun. When the skin is exposed to excessive ultraviolet rays, epidermal cells will be damaged, activating tyrosinase, accelerating a synthesis of pigment, destroying moisturizing function of the skin, drying the skin, damaging elastic fibers in dermis, and causing fine lines. Under strong irradiation, ultraviolet rays can also cause skin inflammation and burns, and when there is an abnormal condition, it will become pigmented skin cancer. On the other hand, proper sun exposure can promote absorption of vitamin D by human body. Therefore, a measurement of an equivalent of personal ultraviolet radiation and a provision of personalized sun protection recommendations based on measurement results are particularly important for personal health.

At present, some intelligent terminal equipment integrates ultraviolet detection function. A basic method is to integrate ultraviolet detectors in non-display areas. Although this method can achieve detection of personal ultraviolet radiation measurement, it is not conducive for increasing a screen-to-body ratio of a terminal device. In order to reduce an impact on the screen-to-body ratio, the ultraviolet detector can be disposed under a display screen. However, absorption of the screen in an ultraviolet band is generally strong, and it is difficult to obtain a more accurate measurement. Therefore, it is necessary to develop an ultraviolet detection device that can be integrated on the display screen.

### SUMMARY OF INVENTION

The present disclosure provides a display panel and manufacturing method thereof, to solve the technical problem of reducing the screen ratio of the display panel due to the addition of ultraviolet detectors in the display panel in the prior art.

The present disclosure provides a display panel, including a display area, a plurality of light-emitting units uniformly distributed in the display area; and at least one organic photodetection unit arranged at an edge or a corner of the display area.

Further, the display panel further includes the organic photodetection unit including an active layer, and a material of the active layer comprises 4,4′,4′-tris (N-3-methylphenyl)-N-phenylamino) triphenylamine and 4,7-diphenyl-1,10-phenanthroline.

Further, the display panel further includes a barrier layer disposed on one side surface of the substrate; a first insulating layer disposed on one side surface of the barrier layer away from the substrate; a second insulating layer disposed on one side surface away from the surface of the barrier layer; a planarization layer disposed on one side surface of the second insulating layer away from the first insulating layer; a plurality of thin film transistor units uniformly disposed on one side surface of the barrier layer, wherein each thin film transistor unit is covered by the first insulating layer, the second insulating layer and the planarization layer; a plurality of conductive units arranged on one side surface of the planarization layer away from the second insulating layer, wherein each conductive unit is connected to one thin film transistor unit; a pixel definition layer arranged on one surface of the planarization layer away from the second insulating layer, wherein the pixel definition layer covers the conductive unit, and the pixel definition layer including pixel openings correspond to each conductive unit.

Further, the display panel further includes a hole injection layer disposed on one side surface of the pixel definition layer away from the planarization layer, wherein the hole transport layer covers an inner wall of the pixel opening and connects to the conductive unit; a hole transport layer disposed on one side surface of the hole injection layer away from the pixel definition layer; a plurality of OLED units disposed on one side surface of the hole transport layer, and correspond to the plurality pixel opening holes.

Further, the display panel further includes an active layer arranged on one side surface of the hole transport layer, and arranged in the plurality of pixel openings on the side of the pixel definition layer.

Further, the display panel further includes an electron transport layer disposed on one side surface of the hole transport layer, and the electron transport layer covers the active layer and the light-emitting layer; an electron injection layer disposed on one side surface of the electron transport layer away from the hole transport layer; a cathode disposed on one side surface of the electron injection layer away from the electron transport layer.

Further, the material of the electron transport layer includes 4,4′,4′-tris (N-3-methylphenyl)-N-phenylamino) triphenylamine, and a material of the hole transport layer comprises 4,7-diphenyl-1,10-phenanthroline.

Further, the display panel further includes a first inorganic layer disposed on one side surface of the cathode layer away from the electron injection layer; an organic layer disposed on one side surface of the first inorganic layer away from the cathode layer.

The present disclosure also provides a method of manufacturing a display panel, the display panel includes a display area and includes the following steps: preparing a number of light-emitting units distributed in an array in the display area, and preparing at least one organic photodetection unit at an edge or a corner of the display area

Further, the specific manufacturing steps of the light-emitting unit and the organic photodetection unit are as follows: preparing a hole injection layer on one side; preparing a hole transport layer on the hole injection layer, a material of the active layer comprises 4,4′,4′-tris(N-3-methylphenyl)-N-phenylamino)triphenylamine and 4,7-diphenyl-1,10-phenanthroline; arranging a plurality of OLED units evenly distributed on the hole transport layer, and preparing at least one active layer at an edge of the hole transport layer; preparing an electron transport layer on the hole injection layer, and the material of the electron transport layer includes 4,4′,4′-tris(N-3-methylphenyl)-N-phenylamino)triphenylamine; preparing an electron injection layer on the transport layer.

The beneficial effect of the present disclosure is that the display panel and the manufacturing method thereof realize ultraviolet detection without affecting the screen ratio of the display panel by arranging organic photoelectric detection units at the edge of the light-emitting layer. The method of manufacturing the display panel, through replacing the OLED unit at the side of the display panel as the active layer and adopting the active layer with a mixed material that can sense ultraviolet rays, realizes ultraviolet detection. The mixed material used in the active layer is the material of the electron transport layer and the hole transport layer, thereby reducing the manufacturing cost.

### DESCRIPTION OF FIGURES

FIG. 1 shows a schematic diagram of a display panel of one embodiment.

FIG. 2 shows a distribution diagram of an active layer on a pixel definition layer of one embodiment.

FIG. 3 shows a distribution diagram of the active layer on the pixel definition layer of other preferred embodiments.

FIG. 4 shows a schematic diagram of a structure of a light-emitting layer of the embodiment.

### DETAILED DESCRIPTION OF PREFERRED EMBODIMENTS

The technical solutions in the embodiments of the present disclosure will be clearly and completely described below in conjunction with the figures in the embodiments of the present disclosure. Obviously, the described embodiments are only a part of the embodiments of the present disclosure, rather than all the embodiments. According to the embodiments in the present disclosure, all other embodiments obtained by those skilled in the art without creative work are within the protection scope of the present disclosure.

### Embodiment

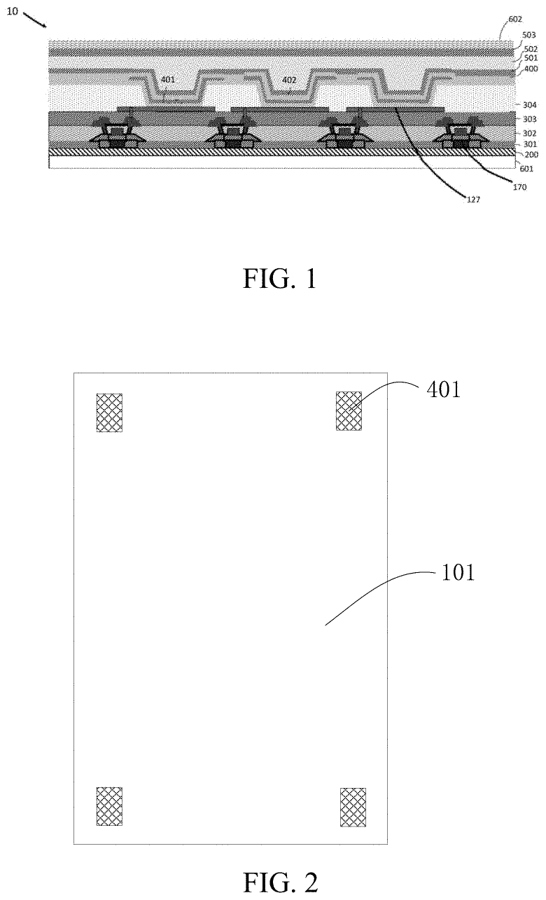

As shown in FIG. 1, in this embodiment, the display panel 10 of the present disclosure includes a substrate 601, a light-emitting layer 120, a barrier layer 200, a first insulating layer 301, a second insulating layer 302, a planarization layer 303, a thin film transistor unit 170, a conductive unit 127, a pixel definition layer 304, and a cathode layer 407.

The substrate 601 is a flexible substrate or a rigid substrate, which is configured to receive the other film layers of the display panel 10 and also used for protection.

The barrier layer 200 is disposed on one side surface of the substrate 601. Since the barrier layer 200 is usually configured to prepare various electrical components and is more sensitive to external water vapor impurities, the barrier layer 200 can isolate external water vapor impurities and improve the service life of the electrical components.

The thin film transistor unit 170 includes an active layer, a gate layer, a source layer, and a drain layer. Specifically, the active layer is disposed on an upper surface of the barrier layer 200, the first insulating layer 301 is disposed on an upper surface of the barrier layer 200, and the first insulating layer 301 covers the active layer. The first insulating layer 301 adopts inorganic materials, the inorganic materials include silicon oxide, or silicon nitride, or a multi-layer thin film structure, configured to buffer and insulate, and prevent short circuits between circuits inside the display panel 10.

The gate layer is disposed on a side surface of the first insulating layer 301 away from the barrier layer 200, and a material of the gate layer is a metal material. The metal material includes molybdenum (Mo), aluminum (Al), copper (Cu), titanium (Ti), etc., or an alloy, or a multilayer film structure. The second insulating layer 302 is disposed on the side surface of the first insulating layer 301 away from the barrier layer 200. The second insulating layer 302 is an interlayer insulating layer. A material of the second insulating layer 302 is an inorganic material, and the inorganic material includes silicon. The second insulating layer 302 covers the gate layer and is configured to insulate and prevent short circuits.

The thin film transistor units 170 are uniformly distributed, and each thin film transistor unit 170 is configured to individually control a light-emitting unit.

The planarization layer 303 covers a side surface of each thin film transistor unit 170 away from the barrier layer 200. The planarization layer 303 makes the surface of each film layer flat, which facilitates the bonding of subsequent film layers and prevents subsequent film layers from detaching.

A plurality of conductive units 127 are disposed on a side surface of the planarization layer 303 away from the thin film transistor unit 170. Each conductive unit 127 corresponds to a thin film transistor unit 170, and each conductive unit 127 penetrates the planarization layer 303 and is connected to the thin film transistor unit 170.

The pixel definition layer 304 is disposed on one side surface of the planarization layer 303 away from the second insulating layer 302. The pixel definition layer 304 has a pixel opening in the area corresponding to each conductive unit 127, wherein the bottom of the pixel opening lies on the conductive units 127 and facilitates the subsequent electrical connection between the light-emitting layer 120 and the conductive unit 127. At the same time, the thin film transistor unit 170 controls a light-darkness of the light-emitting layer 120 through the conductive unit 127 to realize the light-darkness display of the display panel 10.

As shown in FIG. 4, the display panel 10 includes a display area 101. A plurality of light-emitting units 120 and organic photodetection units 121 are distributed on the display area 101, wherein the organic photodetection units 121 are arranged at an edge or a corner of the display area 101, and the light-emitting unit 120 includes a hole injection layer 403, a hole transport layer 404, an OLED unit 402, an electron transport layer 405, an electron injection layer 406, and a cathode layer 407. The organic photodetection unit 121 includes the hole injection layer 403, the hole transport layer 404, an active layer 401, the electron transport layer 405, the electron injection layer 406, and the cathode layer 407, wherein the light-emitting units 120 and the organic photodetection units 121 share the hole injection layer 403, the hole transport layer 404, the electron transport layer 405, the electron injection layer 406, and the cathode layer 407.

The hole injection layer 403 is disposed on one side surface of the pixel definition layer 304 away from the planarization layer 303, and is connected to the conductive unit 127 along an inner wall of the pixel opening. In this embodiment, a material of the hole injection layer 403 may be poly(3,4-ethylenedioxythiophene): polystyrenesulfonate (PEDOT: PSS), in this embodiment, a thickness of the hole injection layer 403 may be 40 nm.

The hole transport layer 404 is disposed on one side surface of the hole injection layer 403 away from the pixel definition layer 304. A material of the hole transport layer 404 can be a p-type organic material, which can be PVK, TFB, Poly-TPD, etc. In this embodiment, the material of the hole transport layer 404 is M-MTDATA material (1,3,5-tris-(3-methylphenylphenylamino)triphenylamine), and a thickness of the hole transport layer 404 is 30 nm-50 nm.

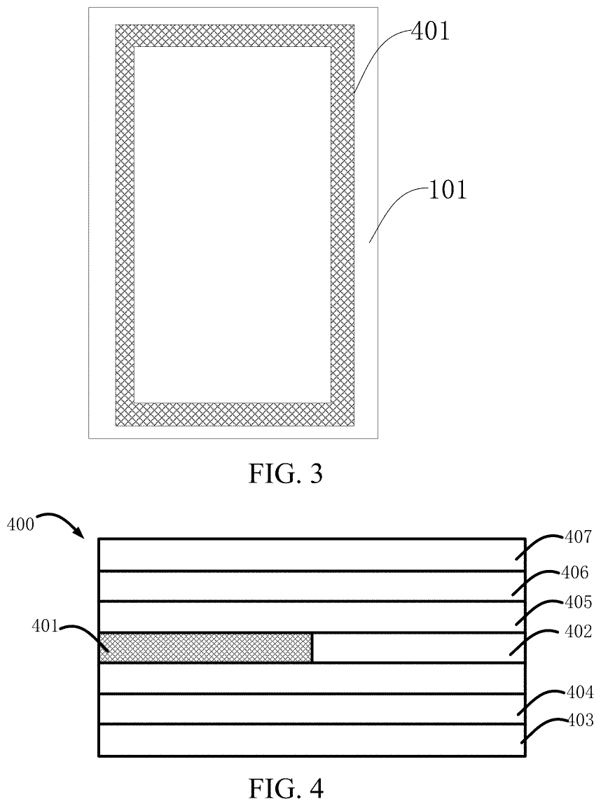

The OLED units 402 are arranged on one side surface of the hole transport layer 404 away from the hole injection layer 403, and can emit light by exciting electrons to realize the display effect of the display panel 10. Specifically, the OLED units 402 are arranged corresponding to the openings of the pixels. At the same time, in order to achieve the technical effect of detecting ultraviolet rays of the present disclosure, in this embodiment, the active layer 401 is disposed on the side surface of the hole transport layer 404 away from the hole injection layer 403, and a material of the active layer 401 is mixed materials, including 4′,4′-tris(N-3-methylphenyl-N-phenylamino)triphenylamine (M-MTDATA4), and 4,7-diphenyl-1,10-phenanthroline (Bphen). Because the material of the active layer 401 cannot emit light, in order to ensure the display quality of the display panel 10, the active layer 401 is provided in the pixel openings on the side of the pixel definition layer 304. As the active layer 401 is very sensitive to ultraviolet rays, only one pixel opening area is required to detect the external ultraviolet intensity. As shown in FIG. 2, in this embodiment, the active layer 401 is provided in the pixel opening at the edge of the pixel definition layer 304. As shown in FIG. 3, in other preferred embodiments of the present disclosure, the active layer 401 may be provided in all the pixel openings around the edge of the pixel definition layer 304 to enhance the sensibility of the external ultraviolet intensity of the display panel 10.

The electron transport layer 405 is disposed on the side surface of the hole transport layer 404 away from the hole injection layer 403, on the OLED unit 402 and the active layer 401. A material of the electron transport layer 405 is small organic molecule or polymer electron transport material. A thickness of the electron transport layer 405 is 1 nm to 100 nm, preferably 20 nm. In this embodiment, the electron transport layer 405 adopts 4,7-diphenyl-1,10-phenanthroline (Bphen). In this embodiment, the material of the hole transport layer 404 adopts 1, 3, 5-tris-(3-methylphenylphenylamino)triphenylamine (M-MTDATA) material, which, mixed with the material of the electron transport layer 405, is the material of the active layer 401, saving the manufacturing steps of the active layer 401 and reducing the manufacturing cost of the active layer 401.

The electron injection layer 406 is disposed on one side surface of the electron transport layer 405 away from the hole transport layer 404. A material of the electron injection layer 406 includes alkali metals and their salts, or alkaline earth metals and their salts, or metal complexes. A thickness of the electron injection layer 406 is 0.5 nm-10 nm, preferably 1 nm.

The hole injection layer 403 transports holes through the hole transport layer 404 and then injects the holes into the OLED units 402, and the electron injection layer 406 transports electrons through the electron transport layer 405 and then injects the electrons into the OLED unit 402 to excite the OLED unit 402 to emit light.

The cathode layer 407 is disposed on a side surface of the electron injection layer 406 away from the electron transport layer 405, and the cathode layer 407 is configured to provide electrons to the electron injection layer 406.

A protective layer 510 is disposed on a side of the light-emitting layer 120 away from the pixel definition layer 304. The protective layer 510 includes a first inorganic layer 501, an organic layer 502, and a second inorganic layer 503, wherein the first inorganic layer 501 is disposed on a side surface of the cathode layer 407 away from the electron injection layer 406. The organic layer 502 is disposed on a side surface of the first inorganic layer 501 away from the cathode layer 407. The second inorganic layer 503 is disposed on a side surface of the organic layer 502 away from the first inorganic layer 501. The protective layer 510 is arranged in an inorganic-organic-inorganic stack, which can effectively isolate external water vapor and achieve the purpose of protecting the electronic components inside the display panel 10.

In order to better explain the present disclosure, this embodiment also provides a manufacturing method of the display panel, which includes the following steps:

Preparing a number of light-emitting units distributed in an array in the display area, and preparing at least one organic photodetection unit at an edge or a corner of the display area, so as not to affect the display quality of the display panel. The organic photoelectric detection unit is configured to detect ultraviolet rays irradiated to the display panel.

Specifically, the specific manufacturing steps of the light-emitting unit and the organic photodetection unit are as follows:

Preparing a hole injection layer;

Preparing a hole transport layer on the hole injection layer, the material of the hole transport layer includes 4,7-diphenyl-1,10-phenanthroline,

Preparing a plurality of OLED units on the hole transport layer, and preparing at least one active layer on one side of the OLED unit;

Preparing an electron transport layer on the hole transport layer, and the material of the electron transport layer includes 4,4′,4′-tris(N-3-methylphenyl)-N-phenylamino)triphenylamine; preparing an electron injection layer on one side of the electron transport layer, wherein the light-emitting units and the organic photodetection units share the hole injection layer, the hole transport layer, the electron transport layer, and the electron injection layer, simplifying the manufacturing steps, and saving the manufacturing cost.

The beneficial effect of the present disclosure is that the display panel and the manufacturing method thereof replace the light-emitting unit at the edge of the light-emitting layer with an active layer, and the active layer adopts a mixed material that can sense ultraviolet rays, thereby making the display panel capable of detecting the intensity of ultraviolet rays. In the display panel, the mixed material used in the active layer is the material of the electron transport layer and the hole transport layer, which reduces the manufacturing cost.

The descriptions of the above embodiments are only used to help understand the technical solutions and core ideas of the present disclosure; those of ordinary skill in the art should understand that they can still modify the technical solutions recorded in the foregoing embodiments, or modify some of the technologies. The features are equivalently replaced; and these modifications or replacements do not cause the essence of the corresponding technical solutions to deviate from the scope of the technical solutions of the embodiments of the present disclosure.

What is claimed is:

1. A display panel, comprising:
a display area;
a plurality of light-emitting units uniformly distributed in the display area; and
at least one organic photodetection unit arranged at an edge or a corner of the display area.

2. The display panel as claimed in claim 1, wherein
the light-emitting units arranged at the edge of the display area are arranged in a straight line with the organic photodetection unit.

3. The display panel as claimed in claim 1, wherein the organic photodetection unit comprises an active layer, and a material of the active layer comprises 4,4′,4′-tris (N-3-methylphenyl)-N-phenylamino) triphenylamine and 4,7-diphenyl-1,10-phenanthroline.

4. The display panel as claimed in claim 3, wherein the light-emitting units comprise:
a pixel definition layer provided with a plurality of pixel openings distributed evenly;
a hole injection layer disposed on one side surface of the pixel definition layer and extended to an inner wall of the pixel openings;
a hole transport layer disposed on one side surface of the hole injection layer away from the pixel definition layer; and
a light-emitting layer arranged on one side surface of the hole transport layer, and the light-emitting layer comprising a plurality of OLED units disposed corresponding to the pixel openings.

5. The display panel as claimed in claim 3, wherein the organic photodetection unit comprises
a pixel definition layer disposed with a plurality of pixel openings distributed evenly;
a hole injection layer disposed on one side surface of the pixel definition layer and extends to an inner wall of the pixel openings;
a hole transport layer disposed on one side surface of the hole injection layer away from the pixel definition layer; and
the active layer arranged on one side surface of the hole transport layer, and arranged in the plurality of pixel openings on one side surface of the pixel definition layer.

6. The display panel as claimed in claim 5, further comprising:
an electron transport layer arranged on the side surface of the hole transport layer and covering the active layer and the light-emitting layer.

7. The display panel as claimed in claim 6, wherein
a material of the electron transport layer comprises 4,4′,4′-tris (N-3-methylphenyl)-N-phenylamino) triphenylamine, and a material of the hole transport layer comprises 4,7-diphenyl-1,10-phenanthroline.

8. A method of manufacturing a display panel, comprising following steps:
preparing a number of light-emitting units distributed in an array in a display area, and
preparing at least one organic photodetection unit at an edge or a corner of the display area.

9. The method of manufacturing the display panel as claimed in claim 8, wherein specific manufacturing steps of the light-emitting units and the organic photodetection unit are as follows:
preparing a hole injection layer on one side;
preparing a hole transport layer on the hole injection layer;
arranging a plurality of OLED units evenly distributed on the hole transport layer, and preparing at least one active layer at an edge of the hole transport layer; and
preparing an electron transport layer on the hole transport layer to cover the plurality of OLED units and the at least one active layer.

10. The method of manufacturing the display panel as claimed in claim 9, wherein
a material of the active layer comprises 4,4′,4′-tris(N-3-methylphenyl)-N-phenylamino)triphenylamine and 4,7-diphenyl-1,10-phenanthroline.
